(19) United States
(12) Patent Application Publication
(10) Pub. No.: US 2025/0366045 A1
(43) Pub. Date: Nov. 27, 2025

(54) STACKED MULTI-GATE DEVICE WITH AN INSULATING LAYER BETWEEN TOP AND BOTTOM SOURCE/DRAIN FEATURES

(71) Applicant: Taiwan Semiconductor Manufacturing Company, Ltd., Hsin-Chu (TW)

(72) Inventors: Wan Chen Hsieh, Hsin-Chu city (TW); Zhen-Cheng Wu, Hsinchu County (TW); Tai-Jung Kuo, Hsinchu City (TW)

(21) Appl. No.: 19/288,124

(22) Filed: Aug. 1, 2025

Related U.S. Application Data
(63) Continuation of application No. 18/475,965, filed on Sep. 27, 2023.
(60) Provisional application No. 63/506,947, filed on Jun. 8, 2023.

(51) Int. Cl. H10D 30/67; H10D 30/01; H10D 30/43; H10D 62/10; H10D 62/13; H10D 64/01; H10D 84/01; H10D 84/03; H10D 84/85

(52) U.S. Cl. CPC H10D 30/6735; H10D 30/014; H10D 30/43; H10D 30/6757; H10D 62/121; H10D 62/151; H10D 64/017; H10D 84/0167; H10D 84/017; H10D 84/038; H10D 84/85

(57) ABSTRACT

Semiconductor structures and methods of forming the same are provided. An exemplary method includes depositing a contact etch stop layer (CESL) and an interlayer dielectric (ILD) layer over a bottom epitaxial source/drain feature formed in a bottom portion of a source/drain trench, etching back the CESL and the ILD layer to expose a top portion of the source/drain trench, performing a plasma-enhanced atomic layer deposition process (PEALD) to form an insulating layer over the source/drain trench, where the insulating layer comprises a non-uniform deposition thickness and comprises a first portion in direct contact with the ILD layer and a second portion extending along a sidewall surface of the top portion of the source/drain trench. Method also includes removing the second portion of the insulating layer and forming a top bottom epitaxial source/drain feature on the second portion of the insulating layer and in the source/drain trench.

### PRIORITY DATA

The present application is a continuation application of U.S. patent application Ser. No. 18/475,965, filed Sep. 27, 2023, which claims the benefit of U.S. Provisional Application No. 63/506,947, filed Jun. 8, 2023, each of which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FETs) where an n-type multi-gate transistor and a p-type multi-gate transistor are stacked vertically, one over the other. Source/drain feature(s) of the n-type multi-gate transistor sometimes are isolated from source/drain feature(s) of the p-type multi-gate transistor by a combination of contact etch stop layer and an interlayer dielectric layer formed over the lower one of the source/drain feature(s) of the C-FET. While existing isolation structures between the lower one of the source/drain feature(s) of the C-FET and the upper one of the source/drain feature(s) of the C-FET are generally adequate, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a method for forming a semiconductor device including a vertical C-FET, according to one or more aspects of the present disclosure.

FIGS. 3A, 3B, 4, 5, 6, 7, 8, 9, 10, 11, 12, 13, 14, and 15 illustrate fragmentary cross-sectional views of a workpiece during various fabrication stages in the method of FIG. 2, according to various aspects of the present disclosure.

FIGS. 16, 17, and 18 illustrate fragmentary cross-sectional views of alternative semiconductor devices, according to one or more aspects of the present disclosure.

FIG. 19 depicts a fragmentary cross-sectional view of the semiconductor device taken along line C-C shown in FIG. 18, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or MBC transistors. In some fabrication processes for forming C-FET devices, the two levels of multi-gate devices are formed sequentially. For example, source/drain features of the bottom multi-gate device (i.e., bottom source/drain features) are formed before source/drain features of the top multi-gate device (i.e., top source/drain features). In some instances, a contact etch stop layer (CESL) and an interlayer dielectric (ILD) layer are first deposited over the bottom source/drain features, and a pre-clean process is performed to the semiconductor structure before the top source/drain features are being deposited. The pre-clean process may damage the interlayer dielectric layer, disadvantageously increasing the risk of electrical short between the top and bottom source/drain features. There is a need to enhance the electrical isolation between top and bottom source/drain features without substantially damaging the channel layers of the top multi-gate device.

The present disclosure provides a method of forming an insulating layer between the bottom source/drain feature and the top source/drain feature without substantially damaging the channel layers of the top multi-gate device. In an embodiment, after etching back a contact etch stop layer (CESL) and an interlayer dielectric (ILD) layer formed on the bottom source/drain feature, a plasma-enhanced atomic layer deposition process (PEALD) is performed to form an insulating layer over the etched CESL and ILD layer. Parameters associated with the PEALD are adjusted such that a horizontal portion of the insulating layer formed on the etched CESL and ILD layer has a greater deposition thickness and better quality than the deposition thickness and quality of a vertical portion of the insulating layer that extends along sidewalls of the channel layers of the top multi-gate device. The vertical portion of the insulating layer is then selectively removed without substantially damaging the channel layers of the top multi-gate device, leaving the horizontal portion on the etched CESL and ILD layer. A top source/drain feature is then formed on the horizontal portion after a pre-clean process is performed. By forming the insulating layer between the top and bottom source/drain features, electrical isolation therebetween is advantageously enhanced, and reliability of the stacked multi-gate device is improved.

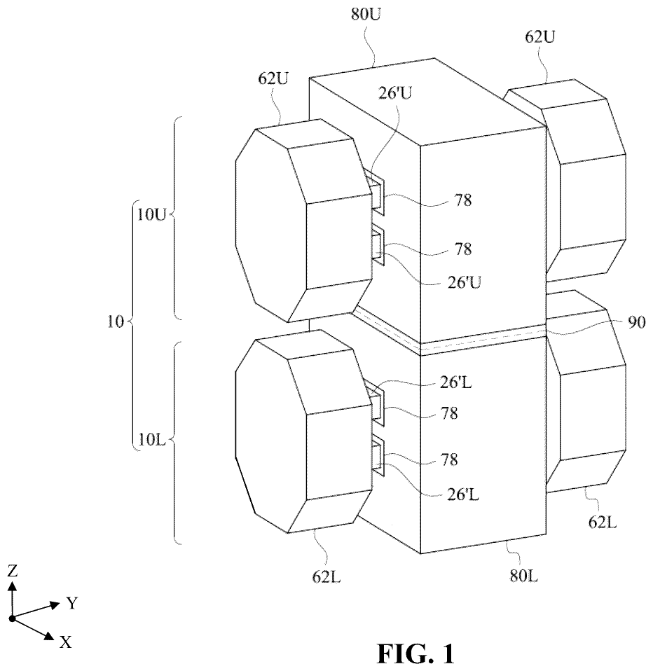

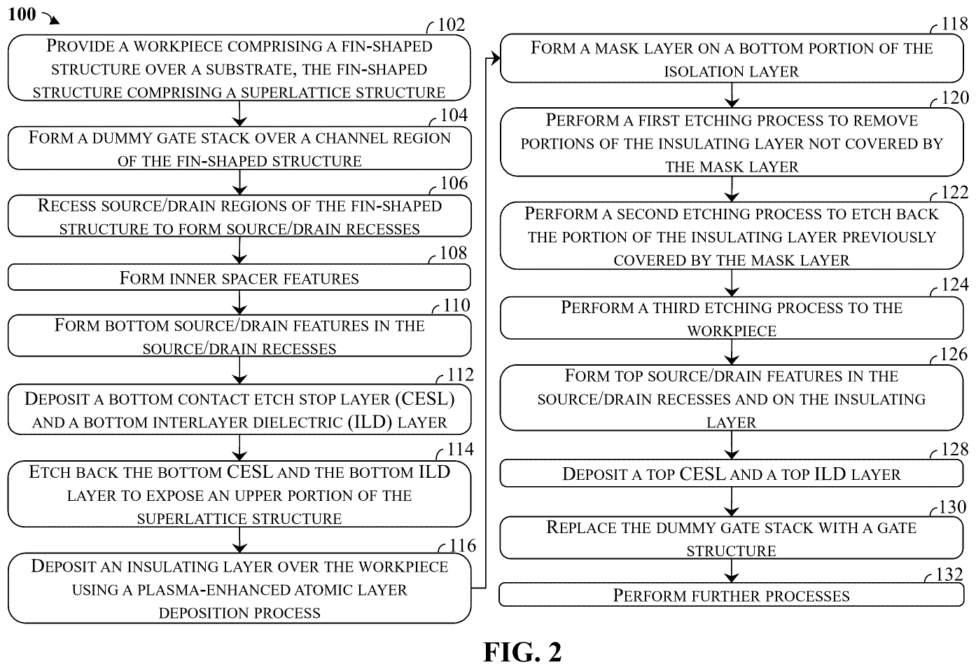

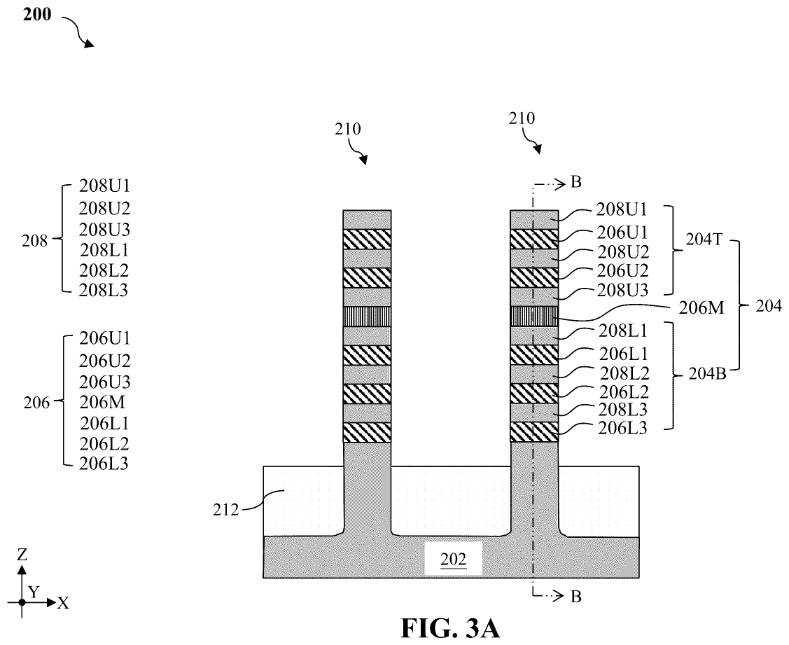

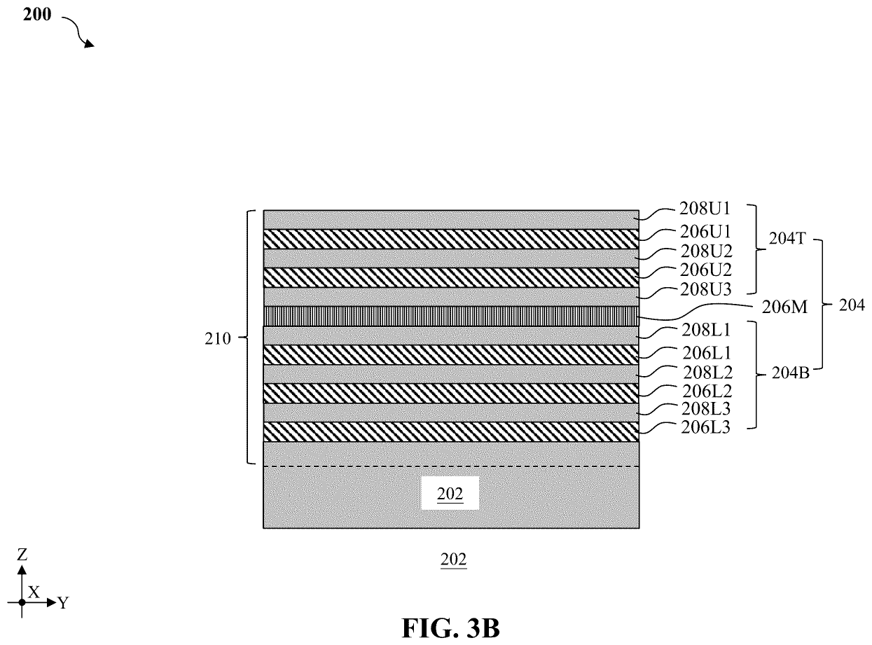

The various aspects of the present disclosure will now be described in more detail with reference to the figures. In that regard, FIG. 1 illustrates a perspective view of a semiconductor device including a vertical C-FET, according to one or more aspects of the present disclosure. FIG. 2 illustrates a flow chart of a method 100 for forming a semiconductor device 200 including a vertical C-FET, according to one or more aspects of the present disclosure. Method 100 is described below in conjunction with FIGS. 3A-19, which are fragmentary cross-sectional views of the workpiece 200 at different stages of fabrication according to embodiments of method 100. Method 100 is merely an example and is not intended to limit the present disclosure to what is explicitly illustrated therein. Additional steps may be provided before, during and after method 100, and some steps described can be replaced, eliminated, or moved around for additional embodiments of the method. Not all steps are described herein in detail for reasons of simplicity. Because the workpiece 200 will be fabricated into a semiconductor device 200 upon conclusion of the fabrication processes, the workpiece 200 may be referred to as the semiconductor device 200 as the context requires. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., C-FET) 10. The semiconductor device 10 includes a lower device 10L (e.g., p-type transistor) and an upper device 10U (e.g., n-type transistor) over the lower device 10L. The lower device 10L includes channel layer 26′L wrapped around by a bottom gate structure. The bottom gate structure includes a gate dielectric layer 78 and a conductive structure 80L. The lower device 10L also includes source/drain features (e.g., p-type epitaxial source/drain features) 62L coupled to the channel layers 26′L and adjacent the bottom gate structure.

The upper device 10U includes channel layer 26′U wrapped around by an upper gate structure. The upper gate structure includes the gate dielectric layer 78 and a conductive structure 80U. The upper device 10U also includes source/drain features (e.g., n-type epitaxial source/drain features) 62U coupled to the channel layers 26′U and adjacent the upper gate structure. An isolation layer 90 is disposed between the upper device 10U and the lower device 10L to electrically insulate the upper gate structure of the upper device 10U from the bottom gate structure of the lower device 10L. The configurations of the elements in the semiconductor device 10 described above are given for illustrative purposes and can be modified depending on the actual implementations. It is understood that some features are omitted in this figure for reason of simplicity.

Referring now to FIGS. 2 and 3A-3B, method 100 includes a block 102 where a workpiece 200 is received. FIG. 3A depicts a cross-sectional view of the workpiece 200, and FIG. 3B depicts a cross-sectional view of the workpiece 200 taken along line B-B shown in FIG. 3A. The workpiece 200 includes a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202. For ease of reference, the substrate 202 and structures formed thereon during the method 100 may be referred to as a workpiece 200.

The workpiece 200 also includes fin-shaped structures 210 formed over the substrate 202. In the present embodiments, the fin-shaped structure 210 is formed from a superlattice structure 204 and a portion of the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a number of channel layers 208 interleaved by a number of sacrificial layers 206. The sacrificial layers 206 and the channel layers 208 are deposited alternatingly, one-after-another, to form the superlattice structure 204. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without inducing substantial damages to the channel layers 208.

For ease of references, the superlattice structure 204 may be vertically divided into a bottom portion 204B, a middle sacrificial layer 206M on the bottom portion 204B, and a top portion 204T on the middle sacrificial layer 206M. In this depicted example, the bottom portion 204B of the super lattice structure 204 includes channel layers 208L1, 208L2 and 208L3 interleaved by sacrificial layers 206L1, 206L2, and 206L3. The top portion 204T of the super lattice structure 204 includes channel layers 208U1, 208U2 and 208U3 interleaved by sacrificial layers 206U1 and 206U2. The channel layers 208L1, 208L2, 208L3, 208U1, 208U2, and 208U3 will provide nanostructures for the C-FET 10. In some embodiments, the channel layers 208U1-208U2, and the channel layers 208L2-208L3 will provide channel members for a top MBC transistor and a bottom MBC transistor in the C-FET 10, respectively. The term “channel member(s)” is used herein to designate any material portion for channel(s) in a transistor with nanoscale dimensions, and having an elongate shape, regardless of the cross-sectional shape of this portion. A germanium content of the middle sacrificial layer 206M may be different from the germanium content of other sacrificial layers (e.g., sacrificial layers 206U1-206U3, sacrificial layers 206L1-206L3) of the top portion 204T and bottom portion 204B. In some embodiments, a germanium content of the middle sacrificial layer 206M may be greater than a germanium content of the other sacrificial layers 206U1-206U3 and 206L1-206L3 such that the entirety of the middle sacrificial layer 206M may be selectively removed during the formation of inner spacer recesses.

It is noted that the superlattice structure 204 in FIGS. 3A-3B includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed between the bottom portion 204B and the top portion 204T. The number of layers depends on the desired number of channels members for the top MBC transistor and the bottom MBC transistor. In some embodiments, the number of the channel layers 208 in the superlattice structure 204 may be between 4 and 10. The thicknesses of the channel layers 208 and the sacrificial layers 206 may be selected based on device performance considerations of the bottom MBC transistor, the top MBC transistor, and the C-FET as a whole.

After forming the superlattice structure 204, the superlattice structure 204 and a portion of the substrate 202 are then patterned to form the fin-shaped structures 210. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 3A-3B, each fin-shaped structure 210 extends vertically along the Z direction from the substrate 202 and extends lengthwise along the Y direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

The workpiece 200 also includes an isolation feature 212 (shown in FIG. 3A) formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the workpiece 200, including the fin-shaped structure 210, using CVD, subatmospheric CVD (SACVD), flowable CVD, spin-on coating, and/or other suitable process. Then the deposited dielectric material is planarized and recessed to form the isolation feature 212. As shown in FIG. 3A, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials.

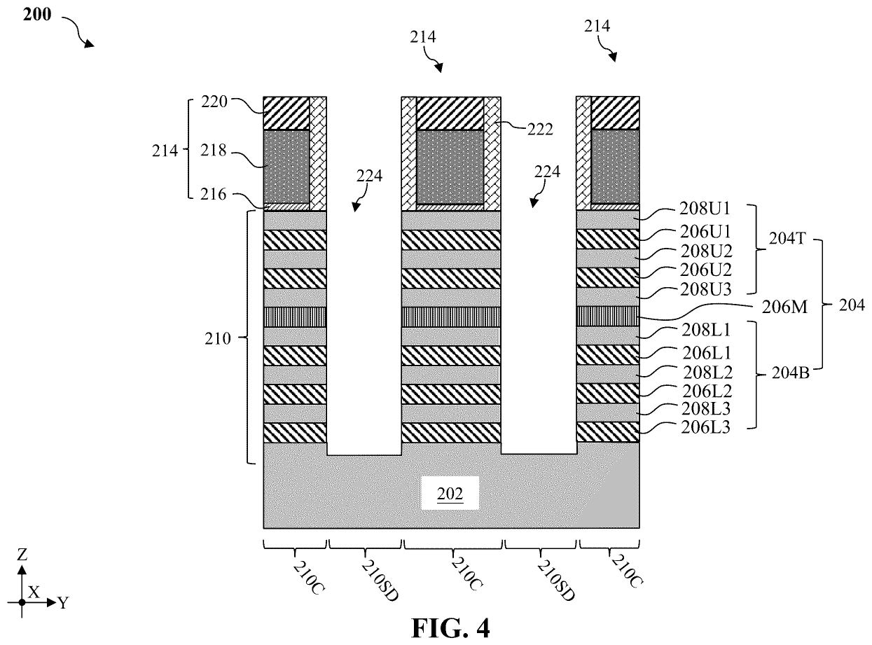

Referring to FIGS. 2 and 4, method 100 includes a block 104 where dummy gate stacks 214 are formed over channel regions 210C of the fin-shaped structure 210. In some embodiments, a gate replacement process (or gate-last process) is adopted where the dummy gate stack 214 serves as a placeholder for a functional gate structure. Other processes and configurations are possible. To form the dummy gate stack 214, a dummy dielectric layer 216, a dummy gate electrode layer 218, and a gate-top hard mask layer 220 are deposited over the workpiece 200. The deposition of these layers may include use of low-pressure CVD (LPCVD), CVD, plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode layer 218 are then etched to form the dummy gate stack 214. The dummy gate stack 214 extends lengthwise along the X direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source or a drain region for forming a drain, individually or collectively dependent upon the context.

Still referring to FIGS. 2 and 4, method 100 includes a block 106 where source/drain regions 210SD of the fin-shaped structure 210 are recessed to form source/drain recesses 224. Operations at block 106 may include formation of at least one gate spacer 222 over the sidewalls of the dummy gate stack 214 before the source/drain regions 210SD are recessed. In some embodiments, the formation of the at least one gate spacer 222 includes deposition of one or more dielectric layers over the workpiece 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the at least one gate spacer 222, an anisotropic etch process is performed to the workpiece 200 to form the source/drain recesses 224. The etch process at block 106 may be a dry etch process or other suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 4, sidewalls of the sacrificial layers 206 and the channel layers 208 in the channel regions 210C are exposed in the source/drain recesses 224.

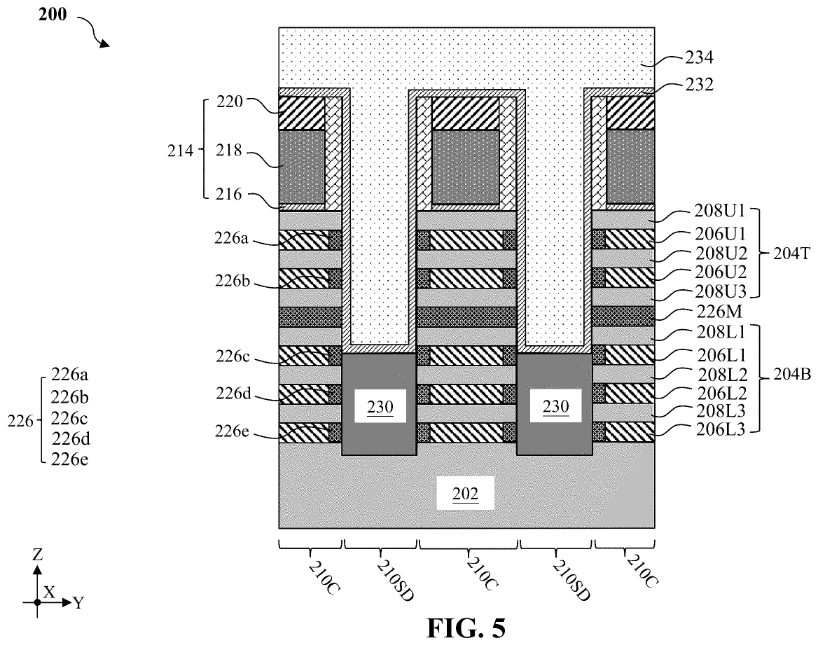

Referring to FIGS. 2 and 5, method 100 includes a block 108 where inner spacer features 226 are formed. At block 108, the sacrificial layers 206 exposed in the source/drain recesses 224 are selectively and partially recessed to form inner spacer recesses, while the exposed channel layers 208 are substantially unetched. The middle sacrificial layer 206M, due to its greater germanium content, may be substantially removed during the formation of inner spacer recesses. In some embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH).

After the formation of the inner spacer recesses, an inner spacer material layer is deposited over the workpiece 200, including in the inner spacer recesses. Additionally, as shown in FIG. 5, the inner spacer material layer may also be deposited in the space left behind by selective removal of the middle sacrificial layer 206M. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess portions of the inner spacer material layer over the dummy gate stack 214, the gate spacer 222, and sidewalls of the channel layers 208, thereby forming the inner spacer features 226 and the middle dielectric layer 226M as shown in FIG. 5. In the present embodiments, the inner spacer features 226 includes inner spacer features 226a and 226b disposed over the middle dielectric layer 226M and inner spacer features 226c, 226d, and 226e disposed under the middle dielectric layer 226M. Each of the inner spacer features 226a-226e and the middle dielectric layer 226M is disposed between two vertically adjacent channel layers 208. For example, the inner spacer feature 226b is disposed between the channel layer 208U2 and the channel layer 208U3, and the inner spacer feature 226c is disposed between the channel layer 208L1 and the channel layer 208L2. In some embodiments, the etch back process at block 108 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

Still referring to FIGS. 2 and 5, method 100 includes a block 110 where bottom source/drain features 230 are formed in the source/drain recesses 224. In some embodiments, before the deposition of the bottom source/drain features 230, a blocking layer (not shown) may be deposited over the workpiece 200 to cover sidewalls of the top portion 204T of the superlattice structure 204. The blocking layer may also cover sidewalls of the middle dielectric layer 226M and the channel layer 208L1. The blocking layer may include dielectric materials. After the formation of the blocking layer, the bottom source/drain features 230 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208 not covered by the blocking layer. In the present embodiments, the epitaxial growth of bottom source/drain features 230 may take place from both the top surface of the substrate 202 and the exposed sidewalls of the bottom channel layers 208L2 and 208L3. The blocking layer, due to its dielectric composition, blocks formation of the bottom source/drain features 230 on sidewalls of the channel layers 208U1-208U3 and 208L1. As illustrated in FIG. 5, the bottom source/drain features 230 are in physical contact with (or adjoining) the channel layers 208L2 and 208L3. Depending on the design, the bottom source/drain features 230 may be n-type or p-type. In the depicted embodiments, the bottom source/drain features 230 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

Still referring to FIGS. 2 and 5, method 100 includes a block 112 where a bottom contact etch stop layer (CESL) 232 and a bottom interlayer dielectric (ILD) layer 234 are deposited over the bottom source/drain features 230. The bottom CESL 232 may include silicon nitride, silicon oxynitride, and/or other materials and may be formed by CVD, ALD, plasma-enhanced chemical vapor deposition (PECVD) process and/or other suitable deposition or oxidation processes. In an embodiment, the bottom CESL 232 includes silicon nitride, and a ratio of nitrogen concentration to silicon concentration (i.e., N/Si) of the bottom CESL 232 is in a range between about 1.1 and about 1.3. In some embodiments, the bottom CESL 232 is first conformally deposited on the workpiece 200 and the bottom ILD layer 234 is deposited over the bottom CESL 232 by spin-on coating, flowable CVD (FCVD), CVD, or other suitable deposition technique. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

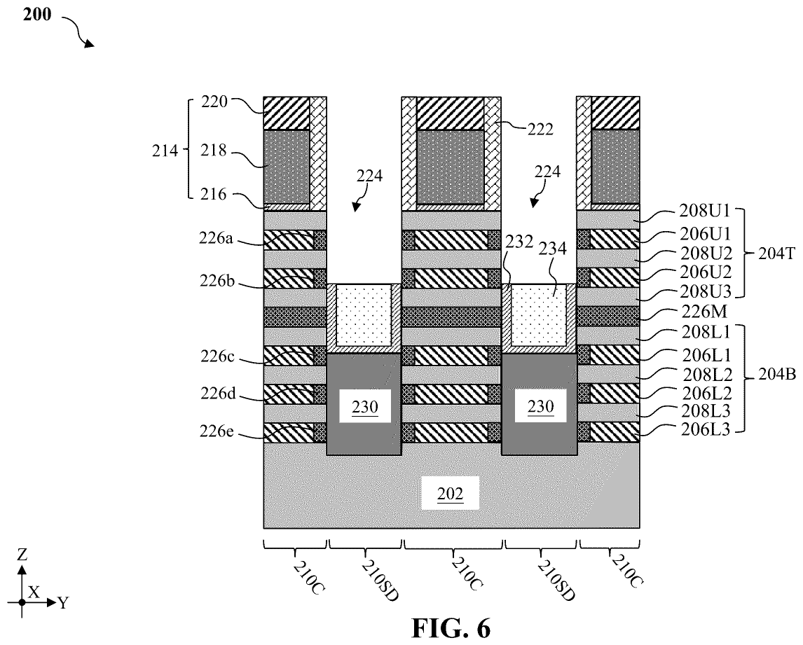

Referring to FIGS. 2 and 6, method 100 includes a block 114 where the bottom CESL 232 and the bottom ILD layer 234 are etched back. As shown in FIG. 6, the bottom CESL 232 and the bottom ILD layer 234 are etched back to exposed sidewalls of the channel layers 208U1 and 208U2. In embodiments presented by FIG. 6, after being etched back, the bottom CESL 232 is in direct contact with the inner spacer features 226b-226c, the channel layers 208U3, 208L1, and the middle dielectric layer 226M. The blocking layer may be removed during the etch back of the bottom CESL 232 and the bottom ILD layer 234.

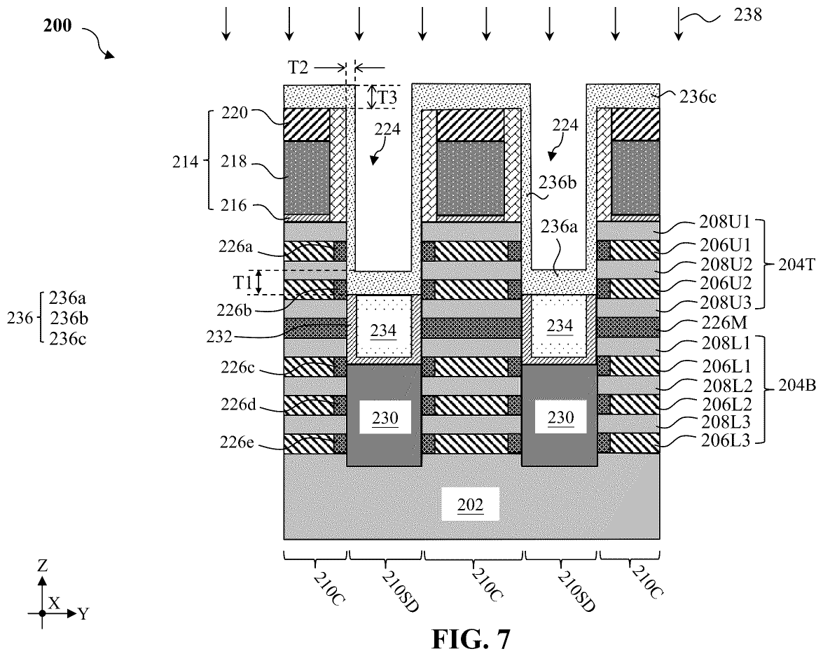

Referring to FIGS. 2 and 7, method 100 includes a block 116 where an insulating layer 236 is deposited over the workpiece 200 by performing a deposition process 238. The insulating layer 236 may include silicon nitride or any other suitable materials. In an embodiment, the insulating layer 236 includes silicon nitride. As depicted in FIG. 7, the insulating layer 236 has a non-uniform deposition thickness over the workpiece 200. Specifically, the insulating layer 236 includes a bottom portion 236a deposited on and in direct contact with a top surface of the bottom CESL 232 and the bottom ILD layer 234, a side portion 236b extending along sidewalls of the gate spacers 222 and sidewalls of the channel layers (e.g., the channel layers 208U1 and 208U2) and inner spacer features (e.g., the inner spacer features 226a and 226b) exposed in the source/drain recesses 224, and a top portion 236c formed on the top surfaces of the dummy gate stacks 214 and gate spacers 222. The bottom portion 236a has a thickness T1 along the Z direction, the side portion 236b has a thickness T2 along the Y direction, and the top portion 236c has a thickness T3 along the Z direction. In the present embodiments, the thickness T1 is greater than the thickness T2. Providing this thickness relationship would facilitate the formation of a satisfactory insulating layer in the final structure of the semiconductor device 200. In the present embodiments, the thickness T3 is also greater than the thickness T2. The thickness T1 may be greater than or equal to the thickness T3.

In the present embodiments, the deposition process 238 includes a plasma-enhanced atomic layer deposition process (PEALD) and may be also referred to as PEALD 238. In PEALD 238, the deposition is achieved by using alternating cycles of precursor gas and plasma exposure. Exemplary steps of one cycle of the PEALD 238 includes, after loading the workpiece 200 into a chamber of the tool performing the PEALD 238, flowing a precursor gas into the chamber. The precursor gas molecules adsorb onto the surface of the workpiece 200, forming a self-limiting monolayer. After the precursor gas exposure, a purge process is performed to purge the precursor gas and any by-products from the chamber. A plasma treatment process that involves flowing a gas into the chamber with charged ions is then performed. During the plasma treatment process, an electromagnetic field, a radiofrequency (RF), or other suitable energy source is applied to direct the ions toward the workpiece 200. The plasma breaks down the precursor molecules and initiates chemical reactions on the surface of the workpiece 200, leading to film growth. The plasma species react with the precursor monolayer on the workpiece 200, resulting in the formation of a thin film. The ionized gas may be removed from the chamber before the next layer deposition cycle is performed.

Parameters of the PEALD 238 are adjusted to form the insulating layer 236 having the non-uniform deposition thickness. In the present embodiments, during the plasma treatment process, the energy source (e.g., electromagnetic field, a radiofrequency (RF)) is adjusted such that surfaces of the workpiece 200 that face up will receive more ions than sidewalls of the workpiece 200 during the PEALD 238. That is, the bottom surface of the source/drain recesses 224 receives more plasma than the sidewall surface of the source/drain recesses 224. As a result, the bottom portion 236a of the insulating layer 236 has the thickness T1 that is greater than the thickness T2 of the side portion of the insulating layer 236. In the present embodiments, since plasma dosage received by the bottom surface of the source/drain recesses 224 is greater than the plasma dosage received by the sidewall surface of the source/drain recesses 224, chemical reaction happened at the bottom surface of the source/drain recesses 224 may be a full reaction, and the chemical reaction happened at the sidewall surface of the source/drain recesses 224 may be a half reaction. As a result, the film quality of the bottom portion 236a of the insulating layer 236 is better than the film quality of the side portion 236b of the insulating layer 236. For example, composition and/or density of the bottom portion 236a of the insulating layer 236 are different than composition and/or density of the side portion 236b of the insulating layer 236, and different composition(s) and/or density provide an etch selectivity between the side portion 236b and the bottom portion 236a of the insulating layer 236. In some embodiments, the top portion 236c has similar composition and density as the bottom portion 236a, and the thickness T3 is substantially equal to the thickness T1 and is greater than the thickness T2.

For embodiments in which the insulating layer 236 includes silicon nitride, the precursor gas may include dichlorosilane (DCS, SiH₂Cl₂), diiodosilane (DIS, SiH₂I₂), or other suitable materials; and the gas implemented in the plasma treatment may include nitrogen (N₂), ammonia (NH₃), or a combination thereof. In some embodiments, the gas implemented in the plasma treatment may further include argon (Ar). In the present embodiments, a ratio of nitrogen concentration to silicon concentration (i.e., N/Si) of the insulating layer 236 is in a range between about 1.7 and about 1.9. That is, N/Si of the insulating layer 236 is greater than the N/Si of the bottom CESL 232. In some embodiments, about 300 cycles to 400 cycles may be performed to achieve the desired deposition thickness (e.g., T1, T2, and T3). The plasma power of provided by the energy source is in a range between about 20 W and about 100 W. If the plasma power is less than 20 W, then the gas may not be satisfactorily ionized to form plasma. If the plasma power is greater than 100 W, then the side portion 236b of the insulating layer may have good quality, and the etch selectivity between the side portion 236b and the bottom portion 236a may be not high enough to ensure the side portion 236b to be selectively removed by a subsequent etching process. In an embodiment, the deposition temperature (e.g., between about 400° C. and about 500° C.) of the PEALD 238 is lower than the deposition temperature (e.g., between about 500° C. and about 700° C.) of the formation of the bottom source/drain features 230 to reduce dopant diffusions and thus substantially keep the dopant concentration of the bottom source/drain features 230.

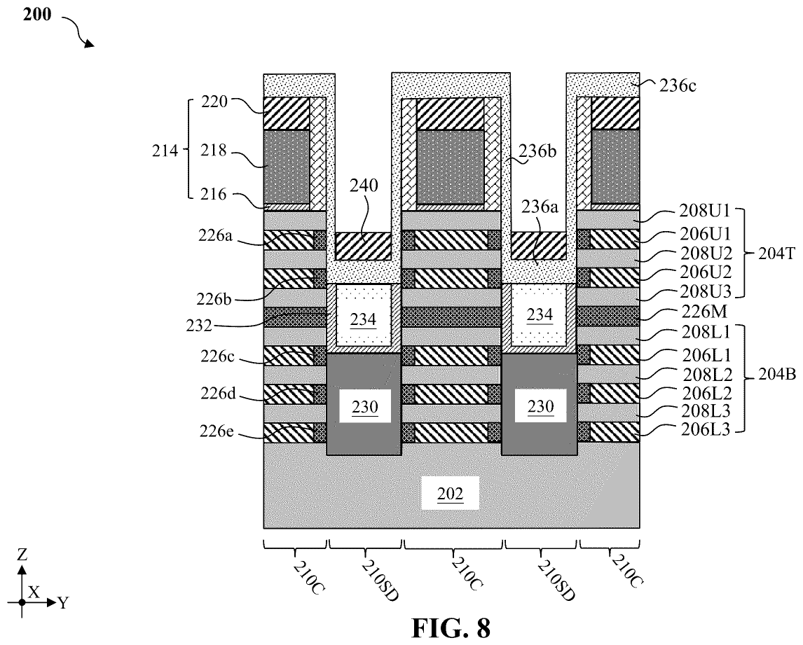

Referring to FIGS. 2 and 8, method 100 includes a block 118 where a mask layer 240 is formed in the source/drain recesses 224 to cover the bottom portion 236a and a lower part of the side portion 236b of the insulating layer 236. In some embodiments, the mask layer 240 is deposited over the workpiece 200 and is patterned to cover the bottom portion 236a of the insulating layer 236 while the top portion 236c is exposed. In one embodiment, the mask layer 240 is a bottom antireflective coating (BARC) layer that may include polysulfones, polyureas, polyurea sulfones, polyacrylates, poly(vinyl pyridine), or a silicon-containing polymer.

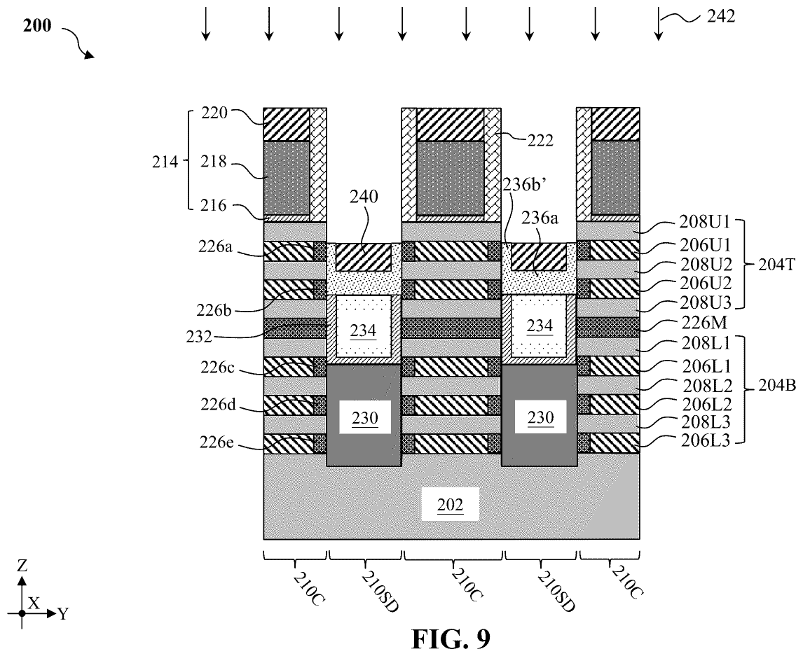

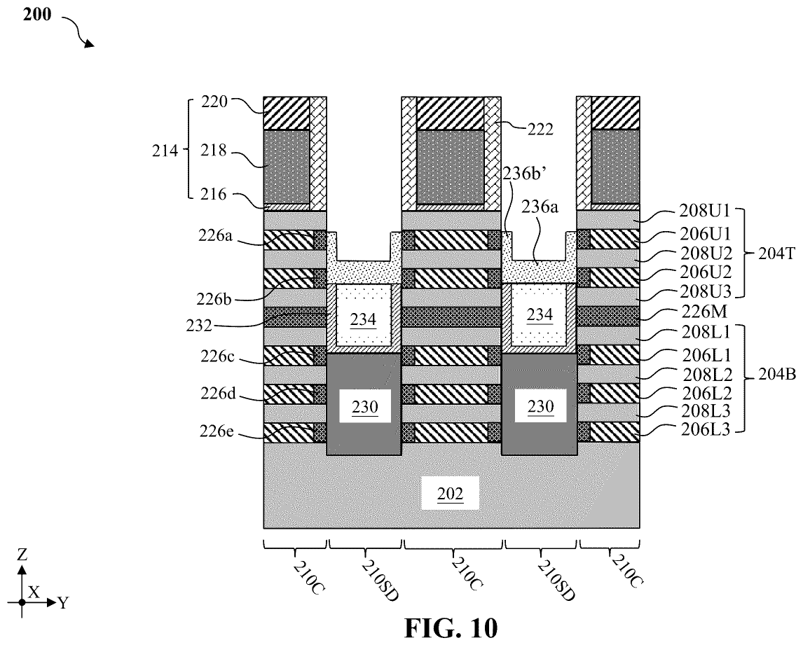

Referring to FIGS. 2 and 9, method 100 includes a block 120 where a first etching process 242 is performed to remove portions of the insulating layer 236 not covered by the mask layer 240. After forming the mask layer 240, the first etching process 242 is performed to selectively etch back the insulating layer 236 without substantially etching the dummy gate stacks 214, the gate spacers 222, and the channel layers 208. In the embodiments, the first etching process 242 selectively removes the top portion 236c and an upper part of the side portion 236b of the insulating layer 236. The first etching process 242 may be an isotropic dry etching and may include hydrogen fluoride (HF), ammonia (NH₃), or a combination thereof. Other suitable etchants may also be implemented by the first etching process 242. The side portion 236b of the insulating layer 236 after the performing of the first etching process 242 may be referred to as side portion 236b′. Referring to FIGS. 2 and 10, after the performing of the first etching process 242, the mask layer 240 is selectively removed without substantially etching the dummy gate stacks 214, the gate spacers 222, the channel layers 208, and the insulating layer 236.

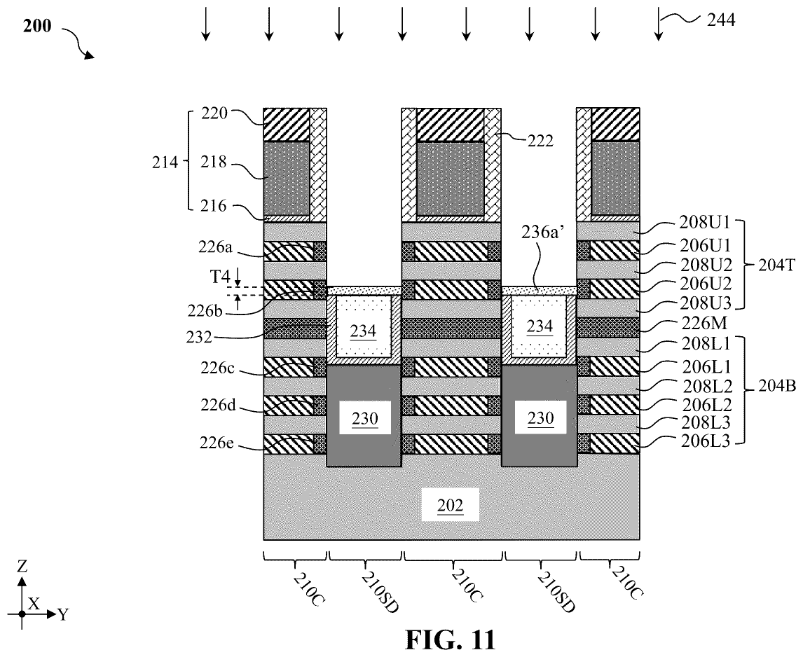

Referring to FIGS. 2 and 11, method 100 includes a block 122 where a second etching process 244 is performed to etch back the insulating layer 236. In some embodiments, the second etching process 244 is an isotropic wet etching process. The etchant of the second etching process 244 may include diluted hydrogen fluoride (HF). In some embodiments, the etchant of the second etching process 244 and the etchant of the first etching process 242 may include the same composition in different states (e.g., hydrogen fluoride solution and hydrogen fluoride gas). The extent at which the insulating layer 236 is recessed is controlled by duration of the second etching process 244. In an embodiment, the performing of the second etching process 244 is stopped when the side portion 236b′ of the insulating layer 236 is fully removed. As described above with reference to FIG. 7, the quality of the bottom portion 236a of the insulating layer 236 is better than the quality of the side portion 236b′ of the insulating layer. In the present embodiments, the etchant(s) of the second etching process 244 etches the side portion 236b′ at a rate greater than it etches the bottom portion 236a. The bottom portion 236a after the performing of the second etching process 244 is referred to as the insulating layer 236a′. The insulating layer 236a′ has a thickness T4. Due to the etch rate difference, a difference between the thickness T1 (shown in FIG. 7) and the thickness T4 (i.e., T1-T4) is less than the thickness T2 of the side portion 236b′ of the insulating layer 236. That is, the extent at which the bottom portion 236a of the insulating layer 236 is recessed is less than that of the side portion 236b. In the present embodiments, as depicted in FIG. 11, an entirety of the sidewall surface of the insulating layer 236a′ is in direct contact with the inner spacer feature 226b. In some embodiments, the thickness T4 is in a range between about 1 nm and about 20 nm to provide enough isolation between the top source/drain features 248 and bottom source/drain features 230 without substantially increasing the fabrication cost.

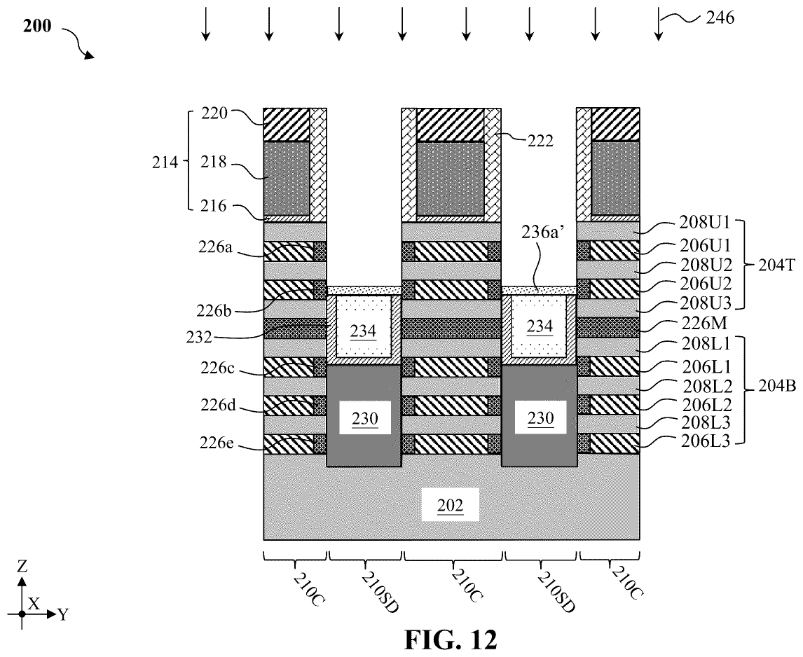

Referring to FIGS. 2 and 12, method 100 includes a block 124 where a third etching process 246 is performed to the workpiece 200. In the embodiments, the third etching process 246 is performed to selectively remove native oxide layer (e.g., silicon oxide) or other by-products formed on the sidewall surfaces of the channel layers (e.g., the channel layers 208U1 and 208U2), on the sidewall surfaces of the inner spacer features (e.g., the inner spacer features 226a and 226b), and/or on the top surface of the insulating layer 236a′ exposed by the source/drain recesses 224 without substantially etching the insulating layer 236a′ to get the workpiece 200 ready for subsequent epitaxial growth process. The third etching process 246 may also be referred to as a pre-clean process 246. In some embodiments, the pre-clean process 246 may include NF₃, NH₃, H₂, or other suitable etchants. In an embodiments, the pre-clean process 246 includes a mixture of NF₃, NH₃, and H₂.

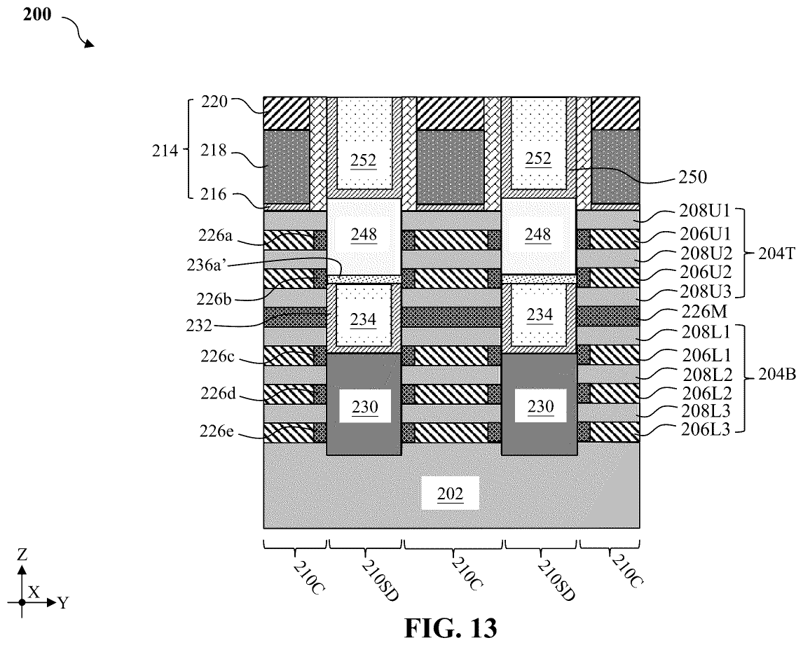

Referring to FIGS. 2 and 13, method 100 includes a block 126 where top source/drain features 248 are formed over the insulating layer 236a′. The top source/drain features 248 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U1 and 208U2) of the top portion 204T of the superlattice structure 204. The epitaxial growth of top source/drain features 248 may take place from the exposed sidewalls of the top channel layers 208U1 and 208U2. The deposited top source/drain features 248 are in physical contact with (or adjoining) the channel layers of the top portion 204T of the superlattice structure 204. Depending on the design, the top source/drain features 248 may be n-type or p-type. In the depicted embodiments, the top source/drain features 248 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

Still referring to FIGS. 2 and 13, method 100 includes a block 128 where a top CESL 250 and a top ILD layer 252 are deposited over the top source/drain features 248. The top CESL 250 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the workpiece 200 and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 252, the workpiece 200 may be annealed to improve integrity of the top ILD layer 252. To remove excess materials and to expose top surfaces of the dummy gate stacks 214, a planarization process, such a chemical mechanical polishing (CMP) process may be performed.

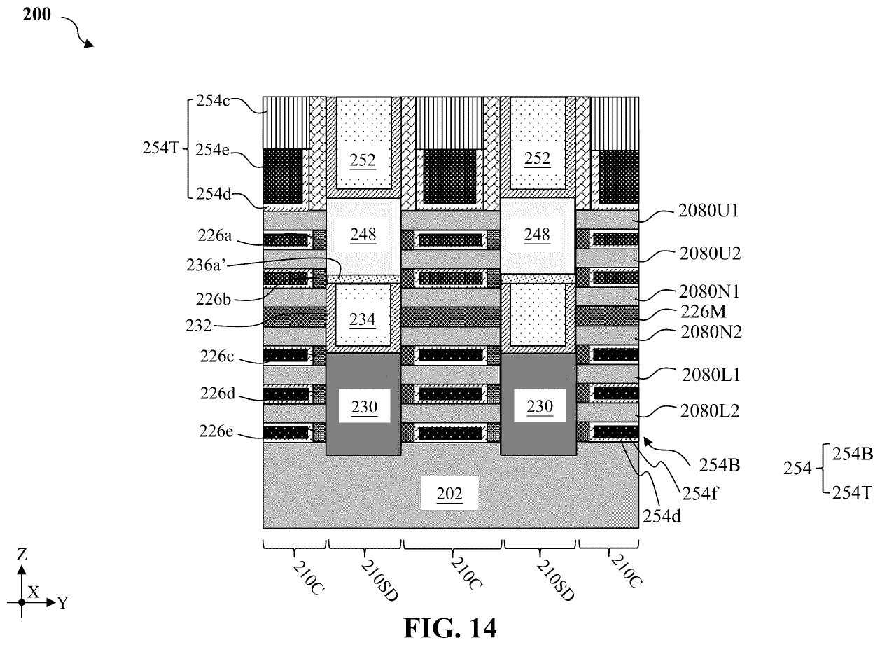

Referring to FIGS. 2 and 14, method 100 includes a block 130 where the dummy gate stack 214 is replaced with a gate structure 254. Operations at block 130 may include removal of the dummy gate stacks 214, release of the channel layers 208 as channel members (including top channel members 2080U1, 2080U2, and bottom channel members 2080L1, and 2080L2) and nanostructures (including the nanostructures 2080N1 and 2080N2) and formation of gate structures 254 to wrap around the channel members 2080. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including the top channel members 2080U1, 2080U2, the bottom channel members 2080L1, and 2080L2) and nanostructures (including the nanostructures 2080N1 and 2080N2). The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

In embodiments represented by FIG. 14, the top channel members 2080U1 and 2080U2 are in direct contact with the top source/drain features 248; the bottom channel members 2080L1 and 2080L2 are in direct contact with the bottom source/drain features 230; and the nanostructures 2080N1, 2080N2 and the middle dielectric layer 226M are in direct contact with the bottom CESL 232.

After the selective removal of the sacrificial layers 206, the gate structure 254 is deposited to wrap around each of the top channel members 2080U1 and 2080U2 and bottom channel members 2080L1 and 2080L2, thereby forming a bottom multi-gate transistor (e.g., 10L in FIG. 1) and a top multi-gate transistor (e.g., 10U in FIG. 1) disposed over the bottom multi-gate transistor. In the depicted embodiments, both the bottom multi-gate transistor and the top multi-gate transistor are MBC transistors. In some embodiments, the gate structure 254 may be a common gate structure to engage the bottom channel members and the top channel members. In some other embodiments depicted in the drawings, the gate structure 254 includes a bottom gate portion 254B to engage bottom channel members 2080L1 and 2080L2 and a top gate portion 254T to engage the top channel members 2080U1 and 2080U2. The bottom gate portion 254B and the top gate portion 254T have different work function layers. When the gate structure 254 includes a bottom gate portion 254B and a top gate portion 254T, the two gate portions may be electrically isolated from each other by the middle dielectric layer 226M. For example, the bottom gate portion 254B may include n-type work function layers and the top gate portion 254T may include p-type work function layers. While not explicitly shown in the figures, the gate structure 254 includes an interfacial layer to interface the channel members. The gate structure 254 also includes a gate dielectric layer 254d over the interfacial layer, a work function layer 254c/254f (e.g., a p-type work function layer or an n-type work function layer). The gate dielectric layer 254d is deposited over the workpiece 200 using ALD, CVD, and/or other suitable methods. The gate dielectric layer 254d is formed of high-K dielectric materials. As used and described herein, high-k dielectric materials include dielectric materials having a high dielectric constant, for example, greater than that of thermal silicon oxide (˜3.9). The gate dielectric layer 254d may include hafnium oxide. Alternatively, the gate dielectric layer 254d may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material.

After the deposition of the gate dielectric layer 254d, n-type work function layer 254e and the p-type work function layer 254f may be formed over the channel regions 210C. The p-type work function layer 254f and the n-type work function layer 254c may include a single layer or alternatively a multi-layer structure, such as various combinations of a metal layer with a selected work function to enhance the device performance (work function metal layer). By way of example, the p-type work function layer 254f may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer 254c may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAIC), titanium aluminum nitride (TiAlN), other n-type work function material, or combinations thereof. The gate structure 254 may also include a metal fill to reduce contact resistance. In some instance, the metal fill includes tungsten (W). The gate structure 254 may also include a liner layer, a wetting layer, an adhesion layer, a metal alloy or a metal silicide. In the depicted embodiment, the top gate portion 254T also includes a dielectric capping layer 254c formed over the n-type work function layer 254c.

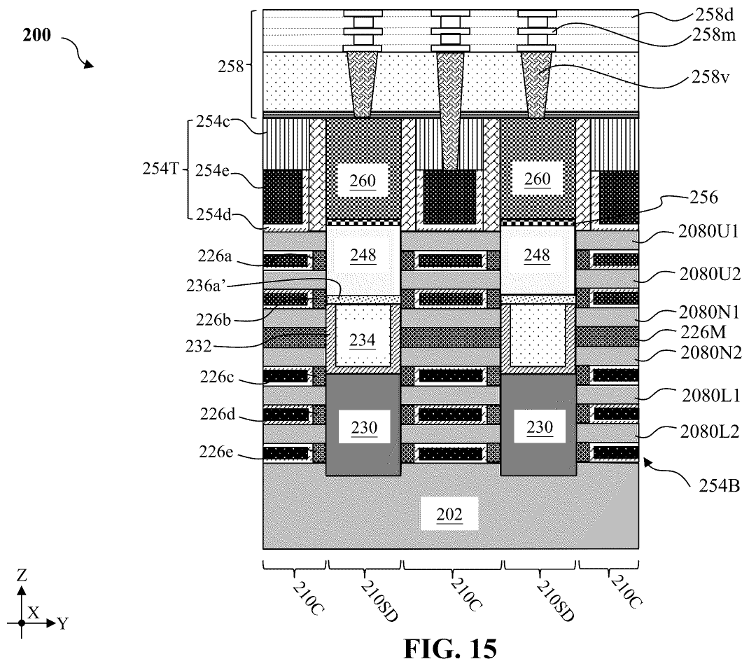

Referring to FIGS. 2 and 15, method 100 includes a block 132 where further processes are performed to complete the fabrication of the semiconductor device 200. Such further processes may include forming a silicide layer 256 over the top source/drain features 248 and forming a multi-layer interconnect (MLI) structure 258 over the workpiece 200. The MLI 258 may include various interconnect features, such as vias 258v and conductive lines 258m, disposed in dielectric layers 258d, such as etch-stop layers and ILD layers. In some embodiments, the vias are vertical interconnect features configured to interconnect device-level contacts, such as source/drain contacts 260 formed over the top source/drain features 248. Other processes may be further performed.

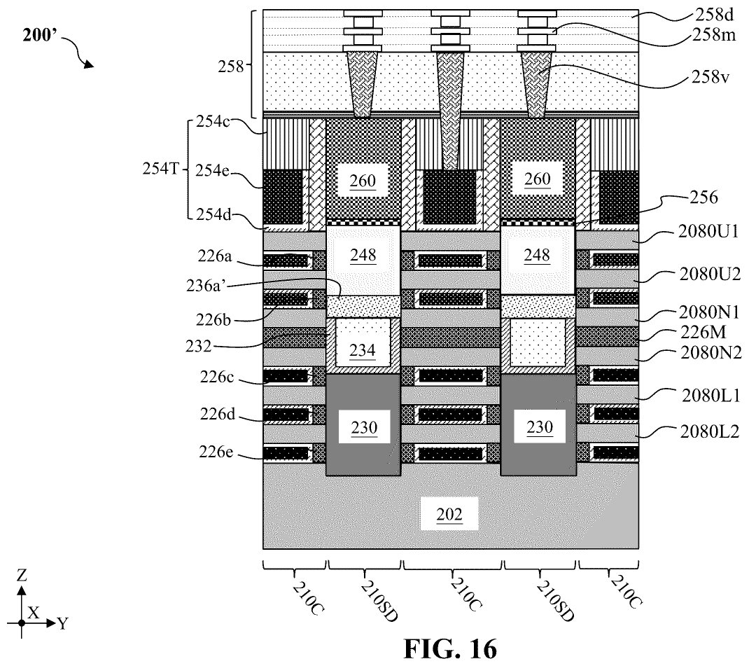

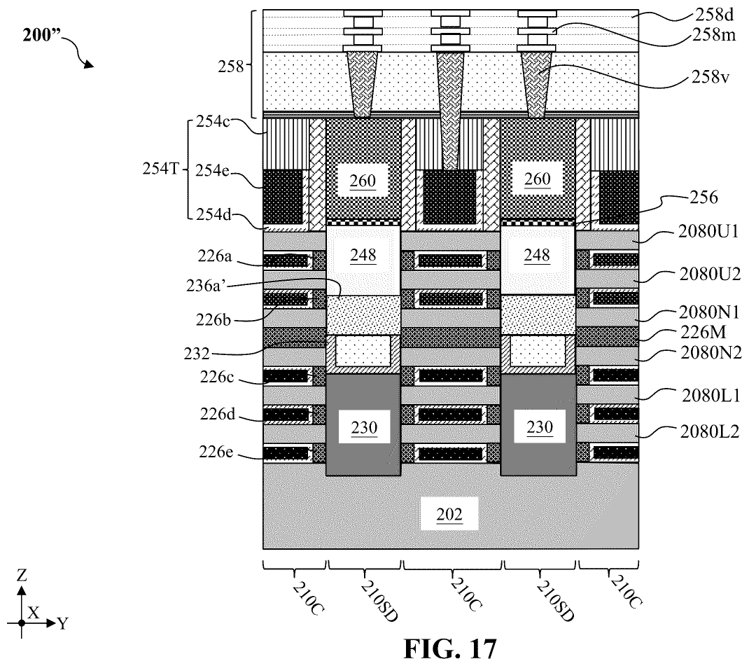

In the above embodiments represented by FIG. 15, an entirety of the sidewall surface of the insulating layer 236a′ is in direct contact with the inner spacer feature 226b. In an alternative embodiment represented by FIG. 16, the sidewall surface of the insulating layer 236a′ is in direct contact with both the inner spacer feature 226b and the nanostructure 2080N1. In another alternative embodiment represented by FIG. 17, the sidewall surface of the insulating layer 236a′ is in direct contact with the inner spacer feature 226b, the nanostructure 2080N1, and the middle dielectric layer 226M.

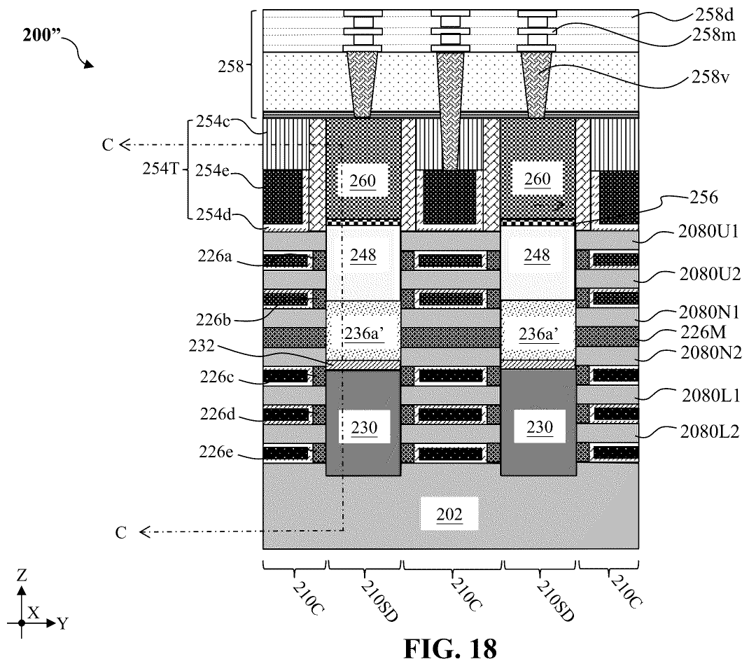

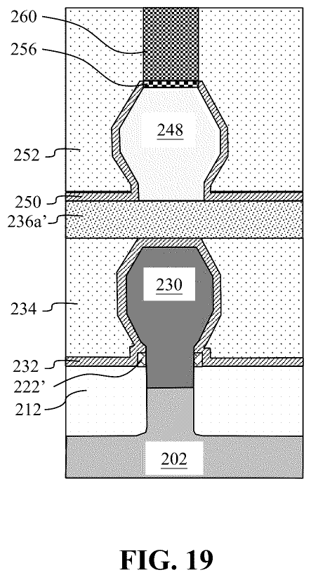

In the above embodiments represented by FIGS. 15-17, the semiconductor device 200 includes the bottom CESL 232 and the bottom ILD layer 234, and the bottom surface of the insulating layer 236a′ is in direct contact with both the bottom CESL 232 and the bottom ILD layer 234. In an alternative embodiment represented by FIG. 18 which is a cross-sectional view of the semiconductor device 200, there is no bottom ILD layer 234 formed on the bottom CESL 232, and an entirety of the bottom surface of the insulating layer 236a′ is in direct contact with the bottom CESL 232. In this alternative embodiment, depending on the total thickness of the bottom CESL 232 and the insulating layer 236a′, an entirety of the sidewall surface of the insulating layer 236a′ may be in direct contact with the inner spacer feature 226b, may be in direct contact with both the inner spacer feature 226b and the nanostructure 2080N1, may be in direct contact with the inner spacer feature 226b, the nanostructure 2080N1, or may be in direct contact with the inner spacer feature 226b, the nanostructure 2080N1, the middle dielectric layer 226M, and the nanostructure 2080N2. FIG. 19 depicts a fragmentary cross-sectional view of the workpiece 200 taken along line C-C shown in FIG. 18. As depicted in FIG. 19, the top source/drain feature 248 is isolated from the bottom source/drain feature 230 by a combination of the bottom CESL 232 and the insulating layer 236a′. The workpiece 200 also includes a fin sidewall spacer 222′ disposed adjacent to the bottom source/drain feature 230. The fin sidewall spacer 222′ may be formed along with the gate spacers 222. Some features are omitted in this figure for reason of simplicity.

Although not intended to be limiting, one or more embodiments of the present disclosure provide many benefits to a semiconductor device and the formation thereof. For example, the present disclosure provides an insulating layer disposed between two vertically adjacent source/drain features to prevent electrical short therebetween, thereby improving the overall reliability of the semiconductor device.

The present disclosure provides for many different embodiments. Semiconductor structures and methods of fabrication thereof are disclosed herein. In one exemplary aspect, the present disclosure is directed to a method. The method includes receiving a workpiece including a fin-shaped structure comprising a channel region and a source/drain region adjacent the channel region, wherein the fin-shaped structure comprises a first semiconductor stack over a substrate and a second semiconductor stack over the first semiconductor stack, and a gate stack over the channel region. The method also includes recessing the source/drain region to form a source/drain trench, forming a first source/drain feature in the source/drain trench and coupled to the first semiconductor stack, depositing a first contact etch stop layer (CESL) and a first interlayer dielectric (ILD) layer over the first source/drain feature, depositing an insulating layer over the workpiece, the insulating layer comprising a horizonal portion on the first ILD layer and a vertical portion extending along a sidewall surface of the second semiconductor stack, wherein a thickness of the horizonal portion is greater than a thickness of the vertical portion, removing the vertical portion of the insulating layer, forming a second source/drain feature on the horizonal portion of the insulating layer, and depositing a second CESL and a second ILD layer over the second source/drain feature.

In some embodiments, the depositing of the insulating layer may include performing a plasma-enhanced atomic layer deposition process (PEALD). In some embodiments, the insulating layer may include silicon nitride, the first CESL may include silicon nitride, and a ratio of nitrogen concentration to silicon concentration of the insulating layer may be different than a ratio of nitrogen concentration to silicon concentration of the first CESL. In some embodiments, the ratio of nitrogen concentration to silicon concentration of the insulating layer may be in a range between about 1.7 and about 1.9. In some embodiments, the depositing of the insulating layer over the workpiece further forms a top portion directly over the gate stack, and a thickness of the top portion may be greater than the thickness of the vertical portion. In some embodiments, the removing of the vertical portion of the insulating layer may include forming a mask layer to cover the horizonal portion of the insulating layer and a lower part of the vertical portion of the insulating layer, performing a first etching process to selectively remove portions of the insulating layer not covered by the mask layer, after the performing of the first etching process, selectively remove the mask layer, and performing a second etching process to remove the lower part of the vertical portion of the insulating layer. In some embodiments, the performing of the second etching process further etches the horizonal portion of the insulating layer, and etchant of the second etching process etches the horizonal portion of the insulating layer at a first rate and etches the lower part of the vertical portion of the insulating layer at a second rate, the second rate is greater than the first rate. In some embodiments, the first semiconductor stack may include a first plurality of channel layers interleaved by a first plurality of sacrificial layers, and the second semiconductor stack may include a second plurality of channel layers interleaved by a second plurality of sacrificial layers, and the method may also include, after the recessing of the source/drain region to form the source/drain trench, performing a third etching process to selectively recess the first plurality of sacrificial layers and the second plurality of sacrificial layers to form a first plurality of inner spacer recesses and a second plurality of inner spacer recesses, respectively, forming a first plurality of inner spacer features in the first plurality of inner spacer recesses and a second plurality of inner spacer features in the second plurality of inner spacer recesses, after depositing the second CESL and the second ILD layer, selectively removing the gate stack, selectively removing the first plurality of sacrificial layers and the second plurality of sacrificial layers, and forming a gate structure over the workpiece. In some embodiments, the fin-shaped structure further may include a silicon germanium layer disposed between the first semiconductor stack and the second semiconductor stack, and the performing of the third etching process further removes the silicon germanium layer to form a space, wherein the forming the first plurality of inner spacer features and the second plurality of inner spacer features further forms a dielectric layer in the space. In some embodiments, the horizonal portion of the insulating layer is in direct contact with a bottommost inner spacer feature of the second plurality of inner spacer features. In some embodiments, the method may also include, after the removing the vertical portion of the insulating layer and before the forming of the second source/drain feature over the horizonal portion of the insulating layer, performing an etching process to pre-clean the workpiece, wherein the etching process does not substantially etch the horizonal portion of the insulating layer.

In another exemplary aspect, the present disclosure is directed to a method. The method includes depositing a contact etch stop layer (CESL) and an interlayer dielectric (ILD) layer over a bottom epitaxial source/drain feature, wherein the bottom epitaxial source/drain feature is formed in a bottom portion of a source/drain trench, etching back the CESL and the ILD layer to expose a top portion of the source/drain trench, performing a plasma-enhanced atomic layer deposition process (PEALD) to form an insulating layer over the source/drain trench, wherein the insulating layer may include a non-uniform deposition thickness and may include a first portion in direct contact with the ILD layer and a second portion extending along a sidewall surface of the top portion of the source/drain trench, removing the second portion of the insulating layer, and forming a top bottom epitaxial source/drain feature on the second portion of the insulating layer and in the top portion of the source/drain trench.

In some embodiments, during the PEALD, a bottom surface of the top portion of the source/drain trench receives a first plasma dosage, and the sidewall surface of the top portion of the source/drain trench receives a second plasma dosage less than the first plasma dosage. In some embodiments, film quality of the first portion of the insulating layer may be better than film quality of the second portion of the insulating layer. In some embodiments, the removing of the second portion of the insulating layer may include forming a mask layer to cover the first portion of the insulating layer and a lower part of the second portion of the insulating layer, performing a first etching process to selectively remove an upper part of the second portion of the insulating layer, selectively remove the mask layer, and performing a second etching process to etch back the insulating layer to remove the lower part of the second portion of the insulating layer. In some embodiments, etchant of the second etching process may etch the lower part of the second portion of the insulating layer faster than it etches the first portion of the insulating layer. In some embodiments, composition of the insulating layer may be different than composition of the CESL and composition of the ILD layer.

In yet another exemplary aspect, the present disclosure is directed to a semiconductor device. The semiconductor device includes a substrate, a lower source/drain feature disposed over the substrate, a first plurality of nanostructures coupled to the lower source/drain feature, a first gate structure wrapping around each of the first plurality of nanostructures, a contact etch stop layer (CESL) and an interlayer dielectric (ILD) layer over the lower source/drain feature, an insulating layer over and in contact with the CESL and the ILD layer, wherein a ratio of nitrogen concentration to silicon concentration of the insulating layer is greater than a ratio of nitrogen concentration to silicon concentration of the CESL, an upper source/drain feature over the insulating layer, a second plurality of nanostructures coupled to the upper source/drain feature, and a second gate structure wrapping around each of the second plurality of nanostructures.

In some embodiments, the first gate structure and the second gate structure may be vertically spaced apart from one another by a dielectric layer. In some embodiments, a sidewall of the dielectric layer may be in contact with the insulating layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first active region comprising a first channel region and a first source/drain feature;
a first gate structure disposed over the first channel region, wherein the first gate structure comprises a gate dielectric layer and at least one metal layer over the gate dielectric layer;
a gate spacer disposed along a sidewall of the first gate structure, wherein a dielectric constant of the gate dielectric layer is greater than a dielectric constant of the gate spacer;
a second active region comprising a second channel region and a second source/drain feature, wherein the second source/drain feature is vertically overlapped with the first source/drain feature;
a contact etch stop layer (CESL) disposed between the first source/drain feature and the second source/drain feature;
an interlayer dielectric (ILD) layer over the CESL; and
an insulating layer extending on the CESL and the ILD layer, wherein a composition of the insulating layer is different from composition of the CESL and the ILD layer.

2. The semiconductor device of claim 1, wherein the insulating layer and CESL comprise silicon nitride with different nitrogen concentrations.

3. The semiconductor device of claim 2, wherein a ratio of nitrogen concentration to silicon concentration of the insulating layer is greater than a ratio of nitrogen concentration to silicon concentration of the CESL.

4. The semiconductor device of claim 1, further comprising:
a second gate structure disposed over the second channel region, wherein the second gate structure is vertically overlapped with the first gate structure.

5. The semiconductor device of claim 4, wherein the first gate structure comprises an n-type work function metal layer, and the second gate structure comprises a p-type work function metal layer.

6. The semiconductor device of claim 1, wherein the first channel region comprises one or more first channel layers, the second channel region comprises one or more second channel layers, and the semiconductor device further comprises one or more nanostructures vertically disposed between the one or more first channel layers and the one or more second channel layers.

7. The semiconductor device of claim 6, further comprising:
a dielectric layer disposed between the one or more first channel layers and the one or more second channel layers and adjacent to the CESL.

8. The semiconductor device of claim 6, wherein the insulating layer extends along a portion of a sidewall surface of the one or more nanostructures.

9. The semiconductor device of claim 6, further comprising:
a first plurality of inner spacers disposed laterally adjacent to the first source/drain feature; and
a second plurality of inner spacers disposed laterally adjacent to the second source/drain feature.

10. The semiconductor device of claim 9, wherein the insulating layer extends along a portion of a sidewall surface of a bottommost inner spacer of the first plurality of inner spacers.

11. The semiconductor device of claim 1, wherein the first source/drain feature and the second source/drain feature comprise dopants having different dopant polarities.

12. A semiconductor device, comprising:
a substrate;
an active region disposed over the substrate and extending lengthwise along a first direction;
an isolation feature disposed over the substrate and alongside the active region;
a first source/drain feature disposed over the active region, wherein a portion of the first source/drain feature overhangs the isolation feature along a second direction different from the first direction;
an etch stop layer extending over the isolation feature and the first source/drain feature;
an interlayer dielectric (ILD) layer disposed over the isolation feature and the etch stop layer;
a second source/drain feature over the first source/drain feature; and
an insulating layer separating the first source/drain feature and the second source/drain feature, wherein the insulating layer extends on the ILD layer.

13. The semiconductor device of claim 12, wherein, a ratio of nitrogen concentration to silicon concentration of the insulating layer is greater than a ratio of nitrogen concentration to silicon concentration of the etch stop layer.

14. The semiconductor device of claim 12, wherein the second source/drain feature is vertically spaced apart from the first source/drain feature by the insulating layer, the etch stop layer, and the ILD layer.

15. The semiconductor device of claim 12, further comprising:
a fin sidewall spacer disposed adjacent to a lower portion of the first source/drain feature, wherein the etch stop layer further extends along a sidewall surface of the fin sidewall spacer.

16. The semiconductor device of claim 12, wherein, in a cross-sectional view cut through the first source/drain feature and the isolation feature, a top surface of the etch stop layer is coplanar with a top surface of the ILD layer.

17. A semiconductor device, comprising:
an upper transistor comprising:
a first active region extending lengthwise along a first direction and comprising a first source/drain feature,
a first gate structure extending lengthwise along a second direction different from the first direction,
a first interlayer dielectric (ILD) layer disposed over the first source/drain feature,
a source/drain contact disposed in the first ILD layer to electrically couple to the first source/drain feature;
a lower transistor comprising:
a second active region extending lengthwise along the first direction and comprising a second source/drain feature,
a second gate structure extending lengthwise along the second direction, and
a second interlayer dielectric (ILD) layer disposed over the second source/drain feature and under the first source/drain feature;
a first dielectric layer disposed between the first gate structure and the second gate structure; and
a second dielectric layer disposed between the first source/drain feature and the second ILD layer.

18. The semiconductor device of claim 17, wherein a top surface of the first dielectric layer is lower than a top surface of the second dielectric layer.

19. The semiconductor device of claim 18, wherein the second dielectric layer extends along a portion of a sidewall surface of the first dielectric layer.

20. The semiconductor device of claim 17, further comprising:
a first nanostructure disposed between the first active region and the first dielectric layer; and
a second nanostructure disposed between the second active region and the first dielectric layer.
